(19) United States
(12) Patent Application Publication
(10) Pub. No.: US 2013/0134836 A1
(43) Pub. Date: May 30, 2013

(54) MULTILAYER CERAMIC ELECTRONIC COMPONENT AND METHOD OF MANUFACTURING THE SAME

(71) Applicants: Seok Joon HWANG, Anyang (KR); Je Jung KIM, Suwon (KR); Jae Yeol CHOI, Seongnam (KR); Sang Hoon KWON, Suwon (KR)

(72) Inventors: Seok Joon HWANG, Anyang (KR); Je Jung KIM, Suwon (KR); Jae Yeol CHOI, Seongnam (KR); Sang Hoon KWON, Suwon (KR)

(73) Assignee: SAMSUNG ELECTRO-MECHANICS CO., LTD.

(21) Appl. No.: 13/524,521

(22) Filed: Jun. 15, 2012

(30) Foreign Application Priority Data
Nov. 25, 2011 (KR) 10-2011-0124430

(51) Int. Cl. H01L 41/047; H05K 3/00; H01F 5/00; H01C 7/10; H01G 4/008

(52) U.S. Cl. 310/363; 338/22 R; 361/305; 336/200; 29/829

(57) ABSTRACT

There is provided a multilayer ceramic electronic component, including: a ceramic element having a plurality of dielectric layers laminated therein; and first and second internal electrodes formed within the ceramic element, wherein the first and second internal electrodes include 80 to 99.9 wt % of copper (Cu) and 0.1 to 20 wt % of nickel (Ni), and a frequency therefor is 1000 MHz or less.

### CROSS-REFERENCE TO RELATED APPLICATIONS

This application claims the priority of Korean Patent Application No. 10-2011-0124430 filed on Nov. 25, 2011, in the Korean Intellectual Property Office, the disclosure of which is incorporated herein by reference.

### BACKGROUND OF THE INVENTION

1. Field of the Invention

The present invention relates to a multilayer ceramic electronic component and a method of manufacturing the same.

2. Description of the Related Art

Electronic components using a ceramic material include a capacitor, an inductor, a piezoelectric element, a varistor, a thermistor, or the like.

Among these ceramic electronic components, a multi-layer ceramic capacitor (MLCC) may have advantages such as a small size, high capacity, and easy mounting thereof.

A multilayer ceramic capacitor is a chip type condenser having a main function of being charged with or discharging electricity while being mounted on a circuit board used in a variety of electronic products, such as a computer, a personal digital assistant (PDA), a cellular phone, and the like. The multilayer ceramic capacitor may have various sizes and lamination types, depending on the intended usage and capacity thereof.

With the recent trend for the miniaturization of electronic products, ultra-miniaturized, ultra-high capacity multi-layer ceramic capacitors have been also been required.

For this reason, a multi-layer ceramic capacitor, in which dielectric layers and internal electrodes are thinly formed for the ultra-miniaturization of products and a large number of dielectric layers are laminated for the ultra-high capacitance thereof, has been manufactured.

Among MLCCs used in high-frequency devices, such as a smart phone, a tablet PC, a laptop, a mobile station, and the like, an RF capacitor used for impedance matching in an area of 500 MHz to 3 GHz has been required to have an improved quality factor Q and various quality factor values for respective capacitances.

However, the level of equivalent series resistance (ESR) is determined depending on the kind of metal constituting an internal electrode and a difference in quality factor Q may be significant depending on metal components. Accordingly, a change ratio in quality factor for a specific capacitance is about 200% or less, there was a limit in freely designing the quality factor (Q) without changing the capacitance of the internal electrode.

### SUMMARY OF THE INVENTION

An aspect of the present invention provides a multilayer ceramic electronic component capable of realizing a predetermined level of equivalent series resistance (ESR) and widening a range of choice in qualify factor (Q), as compared with multilayer ceramic electronic components having the same capacitance, and a method of manufacturing the same.

According to an aspect of the present invention, there is provided a multilayer ceramic electronic part, including: a ceramic element having a plurality of dielectric layers laminated therein; and first and second internal electrodes formed within the ceramic element, wherein the first and second internal electrodes include 80 to 99.9 wt % of copper (Cu) and 0.1 to 20 wt % of nickel (Ni), and a frequency therefor is 1000 MHz or less.

The multilayer ceramic electronic component may have equivalent series resistance (ESR) greater than that of a case in which the first and second internal electrodes are formed of 100 wt % of copper (Cu) and smaller than that of a case in which the first and second internal electrodes are formed of 100 wt % of palladium (Pd).

The equivalent series resistance (ESR) may be 25 to 188 mΩ at a frequency of 100 MHz, proportional to a nickel content of the first and second internal electrodes.

The equivalent series resistance (ESR) may be 28 to 208 mΩ at a frequency of 500 MHz, proportional to a nickel content of the first and second internal electrodes.

The equivalent series resistance (ESR) may be 70 to 228 mΩ at a frequency of 1,000 MHz, proportional to a nickel content of the first and second internal electrodes.

The multilayer ceramic electronic component may further include first and second external electrodes formed on both end surfaces of the ceramic element and electrically connected to the first and second internal electrodes.

The first and second internal electrodes may be alternately exposed through both end surfaces of the ceramic element in a vertical direction.

The multilayer ceramic electronic component may further include dielectric cover layers formed on upper and lower surfaces of the ceramic element.

The multilayer ceramic electronic component may be a high-frequency multilayer ceramic capacitor.

According to another aspect of the present invention, there is provided a method of manufacturing a multilayer ceramic electronic component, the method including: printing a conductive paste including 80 to 99.9 wt % of copper (Cu) and 0.1 to 20 wt % of nickel (Ni) on at least one surface of each of a plurality of first and second ceramic sheets to form first and second internal electrode layers; forming a laminate with a frequency of 1000 MHz by alternately laminating the plurality of the first and second ceramic sheets having the first and second internal electrode layers formed thereon; sintering the laminate; and forming first and second external electrodes to cover surfaces of the laminate, through which the first and second internal electrode layers are exposed.

The forming of the laminate may be performed such that equivalent series resistance (ESR) thereof is greater than that of a case in which the first and second internal electrode layers are formed of 100 wt % of copper (Cu) and smaller than that of a case in which the first and second internal electrode layers are formed of 100 wt % of palladium (Pd).

The forming of the first and second internal electrode layers may be performed such that the first and second internal electrode layers are alternately exposed through both end surfaces of the laminate in a vertical direction.

The method may further include forming dielectric cover layers on upper and lower surfaces of the laminate.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic perspective view showing a structure of a multilayer ceramic capacitor according to an embodiment of the present invention;

FIG. 2 is a cross-sectional view of line A-A′ of FIG. 1;

FIG. 3 is a graph showing equivalent series resistance (ESR) of a multilayer ceramic capacitor according to components of an internal electrode shown in Table 1; and

FIG. 4 is a graph showing a quality factor (Q) of a multilayer ceramic capacitor according to components of an internal electrode shown in Table 2.

### DETAILED DESCRIPTION OF THE PREFERRED EMBODIMENT

Hereinafter, embodiments of the present invention will be described in detail with reference to the accompanying drawings so that they can be easily practiced by those skilled in the art to which the present invention pertains.

However, the invention may be embodied in many different forms and should not be construed as being limited to the embodiments set forth herein.

The embodiments of the present invention are provided so that those skilled in the art may more completely understand the present invention.

In the drawings, the shapes and dimensions may be exaggerated for clarity, and the same reference numerals will be used throughout to designate the same or like components.

In addition, like reference numerals denote elements performing similar functions and actions throughout the drawings.

In addition, unless explicitly described otherwise, “comprising” any components will be understood to imply the inclusion of other components but not the exclusion of any other components.

The present invention is directed to a ceramic electronic component, and the ceramic electronic component according to an embodiment of the present invention is a multilayer ceramic capacitor, an inductor, a piezoelectric element, a varistor, a chip resistor, a thermistor, or the like. The multilayer ceramic capacitor will be described as one example of the ceramic electronic component as follows.

In addition, the present embodiment will be described by defining surfaces on which first and second external electrodes of a ceramic element are formed as left and right end surfaces, for convenience of explanation.

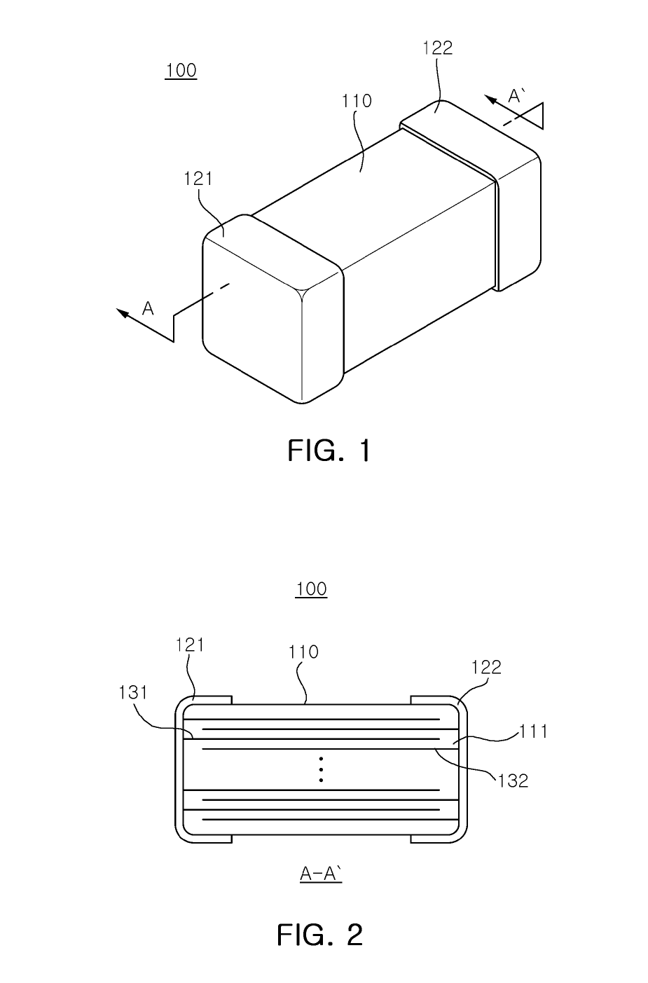

Referring to FIGS. 1 and 2, a multilayer ceramic capacitor 100 according to the embodiment may include a ceramic element 110 having a plurality of dielectric layers 111 laminated therein; and a plurality of first and second internal electrodes 131 and 132 each formed on at least one surface of each of the dielectric layers 111 within the ceramic element 110.

The first and second internal electrodes 131 and 132 may be formed of a conductive paste including conductive metal materials, and the conductive metal materials may include 80 to 99.9 wt % of copper (Cu) and 0.1 to 20 wt % of nickel (Ni).

In this case, equivalent series resistance (ESR) of the multilayer ceramic capacitor 100 may be greater than that of a case in which the first and second internal electrodes 131 and 132 are formed of 100 wt % of copper (Cu) and may be smaller than that of a case in which the first and second internal electrodes 131 and 132 are formed of 100 wt % of palladium (Pd).

In addition, first and second external electrodes 121 and 122 may be formed on both end surfaces of the ceramic element 110 such that they are connected to exposed portions of the first and second internal electrodes 131 and 132.

Here, the first and second external electrodes 121 and 122 may be electrically connected to the respective first and second internal electrodes 131 and 132 to thereby serve as outer terminals.

The ceramic element 110 may be formed by laminating the plurality of dielectric layers 111.

Here, the plurality of dielectric layers 111 constituting the ceramic element 110 may be sintered and integrated such that a boundary between adjacent dielectric layers 111 may not be readily apparent.

Also, the ceramic element 110 is not particularly limited in view of a shape thereof, but may generally have a rectangular parallelepiped shape.

In addition, the size of the ceramic element 110 is not particularly limited, but for example, the ceramic element 110 may be formed to have a size of 0.6 mm×0.3 mm or the like, and thus, this ceramic element 110 may constitute the multilayer ceramic capacitor 100 having high capacitance of 1.0 μF or higher.

In addition, dielectric cover layers (not shown) having a predetermined thickness may be formed on the outermost surfaces of the ceramic element 110, that is, on upper and lower surfaces of the ceramic element 110, in the drawings.

The dielectric cover layers (not shown) are dielectric layers on which the internal electrodes are not formed. As necessary, two or more dielectric cover layers may be laminated in a vertical direction to thereby control the thickness thereof.

The dielectric layers 111 constituting this ceramic element 110 may contain ceramic powder, for example, a BaTiO₃-based ceramic powder or the like.

The BaTiO₃-based ceramic powder may be (Ba₁₋ₓCaₓ)TiO₃, Ba (Ti_{1-y}Ca_{y}) O₃, (Ba₁₋ₓCaₓ) (Ti_{1-y}Zr_{y}) O₃, Ba (Ti_{1-y}Zr_{y}) O₃, or the like, in which, for example, Ca, Zr, or the like is employed in BaTiO₃, but is not particularly limited thereto.

In addition, as necessary, the dielectric layers 111 may further contain at least one of transition metal oxides or carbides, rare earth elements, and magnesium (Mg) or aluminum (Al), together with the ceramic powder.

In addition, a thickness of each dielectric layer 111 may be arbitrarily changed depending on a capacity design of the multilayer ceramic capacitor 100.

The internal electrodes 131 and 132 are formed by printing internal electrode layers on the ceramic green sheets constituting the dielectric layers 111, using a copper-nickel paste through a printing method, such as screen printing or gravure printing. Then, the ceramic green sheets on which the internal electrode layers are printed are alternately laminated and subjected to sintering, thereby forming the ceramic element 110. Therefore, capacitance is formed in an overlapping region in which the first and second internal electrodes 131 and 132 overlap with each other.

Here, the first and second internal electrodes 131 and 132 may have different polarities, and they may be alternately exposed through both end surfaces of the ceramic element 110 in a vertical direction thereof.

In addition, thicknesses of the first and second internal electrode layers 131 and 132 may be determined depending on an intended use thereof or the like, and for example, may be determined within a range of 0.2 to 1.0 μm in consideration of the size of the ceramic element 110. However, the present invention is not limited thereto.

Operations of the multilayer ceramic capacitor 100 of the embodiment configured as above will be described.

In the multilayer ceramic capacitor 100, the internal electrodes may be generally formed of a metal such as copper (Cu), silver (Ag), nickel (Ni), palladium (Pd), or the like.

Among the metals, copper (Cu) or silver (Ag) having excellent electric conductivity may be used to form the internal electrodes, thereby realizing a significantly high quality factor (Q) in a high frequency region.

Palladium (Pd) may exhibit a significantly low quality factor (Q) as compared with copper (Cu) or silver (Ag) in a high frequency region due to a relatively high electric conductivity thereof.

In addition, since nickel (Ni), a ferromagnetic material, has very high permeability (μ), a skin depth for a current flow in a high frequency region is small to cause an increase in equivalent series resistance (ESR), and thus, nickel (Ni) is inappropriate for a multilayer ceramic electronic component for high frequency (“a high-frequency multilayer ceramic electronic component”).

In other words, the level of equivalent series resistance (ESR) of the multilayer ceramic capacitor 100 is determined depending on the metal components constituting the internal electrodes, and a quality factor (Q) of the multilayer ceramic capacitor 100 in a high frequency region is determined by the equivalent series resistance (ESR). In this case, the quality factor (Q) of the multilayer ceramic capacitor 100 may be significantly different according to the metal components constituting the internal electrodes.

Therefore, in order to change the quality factor (Q) of the multilayer ceramic capacitor 100 having a specific capacitance, a method of changing a design of the internal electrode, or changing a thickness of the internal electrode, and the like, may be used. However, in this method, the change ratio in quality factor (Q) may be merely reach 200% or less, and thus, there is a certain limit in freely designing the quality factor (Q) without changing the capacitance of the internal electrode.

In the embodiment, the multilayer ceramic capacitor 100 having high capacitance of 20 pF having a size of 0.6 mm×0.3 mm is used.

Here, in a case in which the first and second internal electrodes 131 and 132 of the multilayer ceramic capacitor 100 are formed of only copper (Cu) or palladium (Pd), when a frequency is generally increased to 10 MHz to 10 GHz, a difference in the quality factor (Q) also may be generated two times to six times due to a difference in specific resistivity (ρ) of a material for the first and second internal electrodes 131 and 132.

In addition, as described above, in a case in which the first and second internal electrodes 131 and 132 are formed of only 100% of copper (Cu) or palladium (Pd), a numerical value of quality factor (Q), which is changed depending on changes in structures or thicknesses of the first and second internal electrodes 131 and 132, is merely about 10 to 30%. Therefore, it is difficult to increase the numerical value of the quality factor (Q) to 200 to 600%, on a desirable level of users, by merely changing the structures or thicknesses of the first and second internal electrodes 131 and 132.

A skin resistance (Rs) of the internal electrode, which influences equivalent series resistance (ESR) at a high frequency, is proportional to electric conductivity (σ), as shown in formula 1 below, and thus, it is inversely proportional to specific resistivity (ρ) of an electric material.

Rs∝\sqrt{fμ/σ} [Formula 1]

In the embodiment, as results of manufacturing chips having the same capacitance and manufactured by using copper-nickel internal electrodes and then measuring the equivalent series resistance (ESR) and quality factor (Q) thereof, a chip manufactured by using internal electrodes including 80 to 99.9 wt % of copper (Cu) and 0.1 to 20 wt % of nickel (Ni) can realize a quality factor (Q) in a middle range between that of a chip having the same capacitance and manufactured by using copper (Cu) internal electrodes and that of a chip having the same capacitance and manufactured by using palladium (Pd) internal electrodes, in a frequency region of 100 MHz to 1 GHz.

In other words, the equivalent series resistance (ESR) and qualify factor (Q) of a multilayer ceramic capacitor at a high frequency can be easily controlled, by merely changing the composition of the internal electrodes to thereby change the specific resistivity (ρ) thereof without changing the capacitance or design of the internal electrodes.

Therefore, by using this principle, a desired value of quality factor (Q) in multilayer ceramic capacitors having the same capacitance at a desired frequency may be designed.

Inventive Examples and Comparative Examples with respect to the present invention will be described in detail with reference to tables 1 and 2 below.

In the embodiment, copper-nickel internal electrodes were formed by adding nickel (Ni) to copper (Cu) in amounts of 0.1 wt %, 5 wt %, 10 wt %, 15 wt %, and 20 wt %, respectively.

Samples 1 and 2 are Comparative Examples with respect to the present invention. Sample 1 indicates a multilayer ceramic capacitor having first and second internal electrodes 131 and 132 formed of copper (Cu), and Sample 2 indicates a multilayer ceramic capacitor having first and second internal electrodes 131 and 132 formed of palladium (Pd).

Samples 3 through 7 are Inventive Examples of the present invention. They indicate multilayer ceramic capacitors having the plurality of first and second internal electrodes 131 and 132 formed of 80 to 99.9 wt % of copper (Cu) and 0.1 to 20 wt % of nickel (Ni) within the ceramic element 110.

Frequencies for the samples were set to 100 MHz, 500 MHz, 1000 MHz, and 3000 MHz, respectively, and then equivalent series resistance (ESR) of the individual multilayer ceramic capacitors for the respective frequencies was measured. The results thereof were tabulated in Tables 1 through 3 below.

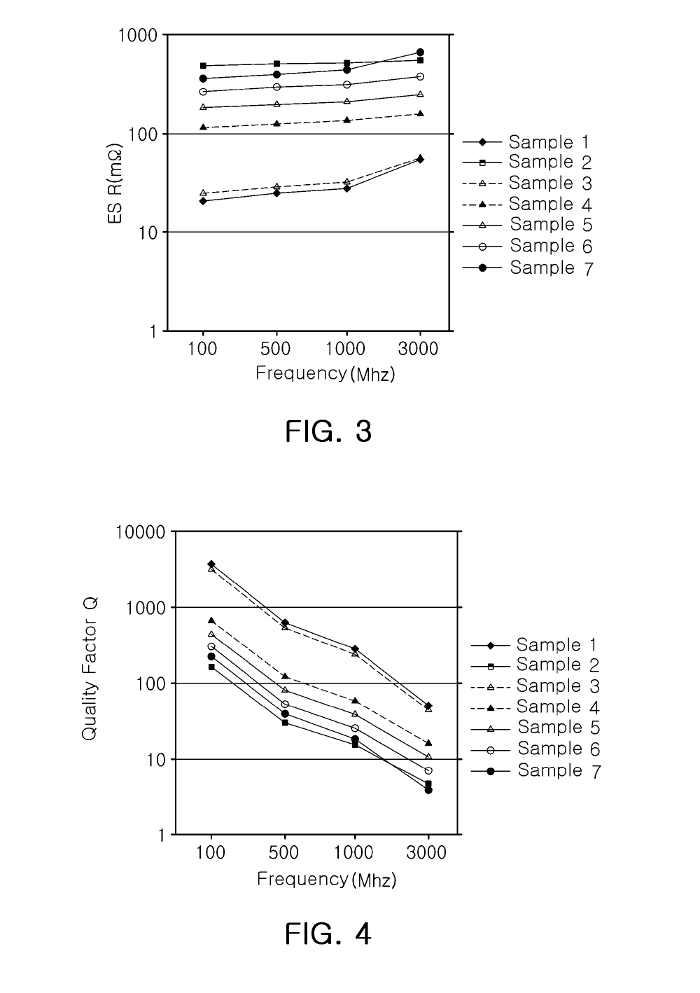

FIG. 3 is a graph showing equivalent series resistance (ESR) of a multilayer ceramic capacitor according to components of an internal electrode shown in Table 1.

TABLE 1

Frequency (MHz)

| Sample | Component | 100 | 500 | 1000 | 3000 |
|---|---|---|---|---|---|
| 1 | Cu | 11 | 13 | 15 | 28 |
| 2 | Pd | 254 | 263 | 269 | 286 |
| 3 | CuNi (Ni 0.1%) | 25 | 28 | 32 | 56 |
| 4 | CuNi (Ni 5%) | 60 | 66 | 70 | 81 |
| 5 | CuNi (Ni 10%) | 94 | 102 | 109 | 127 |
| 6 | CuNi (Ni 15%) | 139 | 153 | 164 | 194 |
| 7 | CuNi (Ni 20%) | 188 | 208 | 228 | 340 |

### <Equivalent Series Resistance (ESR) of Multilayer Ceramic Capacitors According to Components of Internal Electrode>

Referring to Table 1 through FIG. 3, it can be seen that, in Sample 1 as the Comparative Example, equivalent series resistance (ESR) was increased from 11 mΩ to 28 m Ω in accordance with an increase in a frequency from 100 MHz to 3000 MHz, and in Sample 2 as the Comparative Example, the equivalent series resistance (ESR) was increased from 254 mΩ to 286 mΩ in accordance with an increase in a frequency from 100 MHz to 3000 MHz.

In addition, it can be seen that, in Samples 3 through as the Inventive Examples, the equivalent series resistance (ESR) was increased from values of 25 to 139 mΩ to values of 56 to 164 mΩ in accordance with an increase in a frequency from 100 MHz to 3000 MHz, and here, the values of the equivalent series resistance (ESR) in Samples 3 through 6 were between those of Sample 1 and those of Sample 2.

However, in Sample 7, the equivalent series resistance (ESR) was 228 mΩ, which was within the range of Sample 2, until a frequency was increased to 1000 MHz. However, the equivalent series resistance (ESR) was beyond the range of Sample 2 as the frequency was increased to 3000 MHz.

Table 2 below shows a quality factor (Q) of a multilayer ceramic capacitor according to components of an internal electrode, and FIG. 4 is a graph showing a quality factor (Q) of a multilayer ceramic capacitor according to components of an internal electrode shown in Table 2.

TABLE 2

Frequency (MHz)

| Sample | Component | 100 | 500 | 1000 | 3000 |
|---|---|---|---|---|---|
| 1 | Cu | 3703 | 635 | 284 | 50 |
| 2 | Pd | 165 | 32 | 16 | 5 |
| 3 | CuNi (Ni 0.1%) | 3230 | 559 | 252 | 48 |
| 4 | CuNi (Ni 5%) | 694 | 127 | 60 | 17 |
| 5 | CuNi (Ni 10%) | 447 | 82 | 38 | 11 |
| 6 | CuNi (Ni 15%) | 301 | 55 | 25 | 7 |
| 7 | CuNi (Ni 20%) | 222 | 40 | 18 | 4 |

### <Quality Factor (Q) of Multilayer Ceramic Capacitor According to Components of Internal Electrode>

Referring to Tables 2 through 4, it can be seen that, in Sample 1 as the Comparative Example, a quality factor (Q) was decreased from 3703 to 50 in accordance with an increase in a frequency from 100 MHz to 3000 MHz, and in Sample 2 as the Comparative Example, the quality factor (Q) was decreased from 165 to 5 in accordance with an increase in a frequency from 100 MHz to 3000 MHz.

In addition, it can be seen that, in Samples 3 through 6 as the Inventive Examples, quality factors (Q) were decreased from values of 3230 to 301 to values of 48 to 7 in accordance with an increase in a frequency from 100 MHz to 3000 MHz, and here, the values of the quality factors (Q) in the Samples 3 through 6 were between those of Sample 1 and those of Sample 2.

However, it can be seen that, in Sample 7, the value of the quality factor (Q) was 18, which was larger than that of Sample 2, until the frequency was increased to 1000 MHz. However, the value of the quality factor (Q) in Sample 7 was smaller than that of Sample 2 as the frequency was increased to 3000 MHz.

In other words, in the case in which the internal electrodes are formed of 80 to 99.9 wt % of copper (Cu) and 0.1 to 20 wt % of nickel (Ni), specific resistivity (ρ) of the internal electrodes is changed to realize the equivalent series resistance (ESR) in a middle range between that of the internal electrodes formed of copper (Cu) and that of the internal electrodes formed of palladium (Pd), for example, 25 to 188 mΩ at 100 MHz, 28 to 208 mΩ at 500 MHz, and 70 to 228 mΩ at 1000 MHz.

However, if a frequency is above 1000 MHz, the internal electrodes containing a nickel content of 20% are higher than palladium (Pd) internal electrodes in view of equivalent series resistance (ESR) and are lower than the palladium (Pd) internal electrodes in view of quality factor (Q), and thus, it is preferable to set the frequency to be within a range of 1000 MHz or less.

Therefore, it can be anticipated that the qualify factor (Q) is variously changed in the multilayer ceramic capacitor of the same capacitance even without changing the design and thickness of the internal electrodes.

Hereinafter, a method of manufacturing a multilayer ceramic capacitor according to the embodiment of the present invention will be described.

A plurality of ceramic green sheets are prepared.

The ceramic green sheets are to form the dielectric layers 111 of the ceramic element 110, and may be formed by mixing ceramic powder, a polymer, and a solvent to prepare a slurry and then molding the slurry into sheets having a thickness of several μm through doctor blade method or the like.

Then, first and second internal electrode layers each are formed by printing a conductive paste on at least one surface of each of the ceramic green sheets in a predetermined thickness, for example, 0.2 to 1.0 μm.

The conductive paste may include 80 to 99.9 wt % of copper (Cu) and 0.1 to 20 wt % of nickel (Ni).

Here, the first internal electrode layer formed on a first ceramic sheet is exposed through one end surface of the first ceramic sheet, and the second internal electrode layer formed on the second ceramic sheet is exposed through one end surface of the second ceramic sheet.

As a printing method of the conductive paste, screen printing, gravure printing, or the like may be employed. Examples of the conductive paste may include metal powder, ceramic powder, silica (SiO₂) powder, or the like.

The conductive paste may have an average particle size of 50 to 400 nm, but the present invention is not limited thereto.

Thereafter, the first and second ceramic green sheets having the first and second internal electrode layers formed thereon are laminated and pressurized in a lamination direction, such that the plurality of ceramic green sheets laminated and the conductive paste formed on each of the ceramic green sheets are compressed to each other to form a laminate.

Here, the equivalent series resistance (ESR) of the laminate may be greater than that of a case in which the first and second internal electrode layers are formed of 100 wt % of copper (Cu) and may be smaller than that of a case in which the first and second internal electrode layers are formed of 100 wt % of palladium (Pd).

In addition, one or more dielectric cover layers (not shown) may be further laminated on upper and lower surfaces of the laminate.

The dielectric cover layers may have the same composition as that of the dielectric layers 111 positioned within the laminate. The dielectric cover layers may be different from the dielectric layers 111 in that they do not include the internal electrodes.

Thereafter, the laminate is cut into units of a region corresponding to one capacitor and individualized into each chip, and then the chips are sintered at a high temperature, thereby completing the ceramic element 110.

Then, the first and second external electrodes 121 and 122 are formed to cover exposed portions of the first and second internal electrode layers exposed through both end surfaces of the ceramic element 110 to be electrically connected to the first and second internal electrode layers.

Here, as necessary, surfaces of the first and second external electrodes 121 and 122 may be plate-treated with nickel, tin, or the like.

As set forth above, according to the embodiments of the present invention, there is provided a multilayer ceramic electronic component, in which specific resistivity (ρ) of internal electrodes is changed by adding a very small amount of nickel (Ni) to copper (Cu), thereby realizing equivalent series resistance (ESR) in a middle range between that of a case in which palladium (Pd) internal electrodes are used and that of a case in which copper (Cu) internal electrodes are used, while widening the range of choice in qualify factor (Q) as compared with multilayer ceramic electronic components having the same capacitance.

While the present invention has been shown and described in connection with the embodiments, it will be apparent to those in the art that modifications and variations can be made without departing from the spirit and scope of the invention as defined by the appended claims.

What is claimed is:

1. A multilayer ceramic electronic component, comprising:
a ceramic element having a plurality of dielectric layers laminated therein; and
first and second internal electrodes formed within the ceramic element,
wherein the first and second internal electrodes include 80 to 99.9 wt % of copper (Cu) and 0.1 to 20 wt % of nickel (Ni),
and a frequency therefor is 1000 MHz or less.

2. The multilayer ceramic electronic component of claim 1, wherein the multilayer ceramic electronic component has equivalent series resistance (ESR) greater than that of a case in which the first and second internal electrodes are formed of 100 wt % of copper (Cu) and smaller than that of a case in which the first and second internal electrodes are formed of 100 wt % of palladium (Pd).

3. The multilayer ceramic electronic component of claim 2, wherein the equivalent series resistance (ESR) is 25 to 188 mΩ at a frequency of 100 MHz, proportional to a nickel content of the first and second internal electrodes.

4. The multilayer ceramic electronic component of claim 2, wherein the equivalent series resistance (ESR) is 28 to 208 mΩ at a frequency of 500 MHz, proportional to a nickel content of the first and second internal electrodes.

5. The multilayer ceramic electronic component of claim 2, wherein the equivalent series resistance (ESR) is 70 to 228 mΩ at a frequency of 1,000 MHz, proportional to a nickel content of the first and second internal electrodes.

6. The multilayer ceramic electronic component of claim 1, further comprising first and second external electrodes formed on both end surfaces of the ceramic element and electrically connected to the first and second internal electrodes.

7. The multilayer ceramic electronic component of claim 1, wherein the first and second internal electrodes are alternately exposed through both end surfaces of the ceramic element in a vertical direction.

8. The multilayer ceramic electronic component of claim 1, further comprising dielectric cover layers formed on upper and lower surfaces of the ceramic element.

9. The multilayer ceramic electronic component of claim 1, wherein the multilayer ceramic electronic component is a multilayer ceramic capacitor for high-frequency

10. A method of manufacturing a multilayer ceramic electronic component, the method comprising:
printing a conductive paste including 80 to 99.9 wt % of copper (Cu) and 0.1 to 20 wt % of nickel (Ni) on at least one surface of each of a plurality of first and second ceramic sheets to form first and second internal electrode layers;
forming a laminate with a frequency of 1000 MHz or less by alternately laminating the plurality of the first and second ceramic sheets having the first and second internal electrode layers formed thereon;
sintering the laminate; and
forming first and second external electrodes to cover surfaces of the laminate, through which the first and second internal electrode layers are exposed.

11. The method of claim 10, wherein the forming of the laminate is performed such that equivalent series resistance (ESR) thereof is greater than that of a case in which the first and second internal electrode layers are formed of 100 wt % of copper (Cu) and smaller than that of a case in which the first and second internal electrode layers are formed of 100 wt % of palladium (Pd).

12. The method of claim 10, wherein the forming of the first and second internal electrode layers is performed such that the first and second internal electrode layers are alternately exposed through both end surfaces of the laminate in a vertical direction.

13. The method of claim 10, further comprising forming dielectric cover layers on upper and lower surfaces of the laminate.
